(19) United States
(12) Patent Application Publication
(10) Pub. No.: US 2026/0128099 A1
(43) Pub. Date: May 7, 2026

(54) ENERGY-EFFICIENT VECTOR SIMILARITY SEARCH SYSTEM BASED ON HYBRID MATCHING AND METHOD THEREOF

(71) Applicants: NATIONAL TAIWAN UNIVERSITY, Taipei (TW); ACADEMIA SINICA, Taipei (TW)

(72) Inventors: Chi-Tse HUANG, Taipei City (TW); Hao-Wei CHIANG, Taipei City (TW); An-Yu WU, Taipei City (TW); Hsiang-Yun CHENG, Taipei City (TW); Chih-Yu HU, Taipei City (TW)

(73) Assignees: NATIONAL TAIWAN UNIVERSITY, Taipei (TW); ACADEMIA SINICA, Taipei (TW)

(21) Appl. No.: 19/375,242

(22) Filed: Oct. 31, 2025

Related U.S. Application Data
(60) Provisional application No. 63/714,990, filed on Nov. 1, 2024.

(51) Int. Cl. G11C 16/08; G06N 3/063; G11C 16/24; G11C 16/30

(52) U.S. Cl. CPC G11C 16/08; G06N 3/063; G11C 16/24; G11C 16/30

(57) ABSTRACT

An energy-efficient vector similarity search (VSS) system based on hybrid matching and method thereof are disclosed. By combining an exact-search (ES) mode and an approximate-search (AS) mode within memory strings of a flash memory array, the ES mode is performed in a first portion of each memory string to filter out irrelevant memory strings and reduce power consumption, while the AS mode is performed in a second portion of the filtered memory strings to measure vector similarity. Memory strings matching a query vector are selected based on the magnitude of conduction current, thereby significantly reducing redundant searches. The mechanism helps to improve the energy efficiency of VSS.

### BACKGROUND OF THE INVENTION

This application claims the priority benefit of provisional patent application No. 63/714,990 titled “Two-Stage Partial Matching Mechanism for Low-Power Operations of NAND-based Non-Volatile Memory Supporting In-Memory-Search Applications” filed on Nov. 1, 2024, the disclosure of which is incorporated by reference herein in its entirety.

### FIELD OF THE INVENTION

The present invention relates to a vector similarity search system and method thereof, and more particularly, to an energy-efficient vector similarity search system based on hybrid matching and method thereof.

### DESCRIPTION OF THE RELATED ART

In recent years, with the popularization and vigorous development of Artificial Intelligence (AI), various AI applications have emerged rapidly. Among them, Vector Similarity Search (VSS) has attracted the most attention. VSS is the core of many AI applications, such as Few-Shot Learning (FSL) and Approximate Nearest-Neighbor Search (ANNS). These applications require performing efficient VSS in large-scale databases to quickly find stored vectors that are most similar to a query vector. The stored vectors may also be referred to as support vectors.

Generally, traditional VSS requires frequently transferring a large number of high-dimensional vectors stored in external memory (e.g., DRAM) to a central processing unit (CPU) or a graphics processing unit (GPU) for comparison operations. However, when processing large-scale data, this method causes extremely high energy consumption and latency due to massive data movement. As the data scale expands, the energy consumption problem becomes more severe. Therefore, traditional VSS suffers from problems of excessive energy consumption and performance bottlenecks caused by frequent data transfers.

In view of this, manufacturers have proposed in-memory search (IMS) techniques, which perform vector comparisons directly within flash memory, avoiding data movement between memory and processors. However, existing IMS techniques only employ a single approximate search mode to perform full vector comparisons. This results in current generation and energy consumption even for obviously irrelevant vectors, failing to effectively reduce energy consumption. Thus, in large-scale VSS, this is still insufficient to solve the problem of excessive energy consumption.

In summary, it is evident that the prior art has long faced the problem of how to perform large-scale VSS with low power consumption and high efficiency. Therefore, there is a genuine need to propose improved technical means to solve this problem.

### SUMMARY OF THE INVENTION

An objective of the present invention is to disclose an energy-efficient vector similarity search system based on hybrid matching and method thereof.

In order to achieve the objective, the present invention discloses an energy-efficient vector similarity search (VSS) system based on hybrid matching and configured for execution within an in-memory search (IMS) architecture. The system comprises: a flash memory array, a bit line driver circuit, a word line driver circuit, and a sense amplifier circuit. The flash memory array comprises a plurality of word lines, a plurality of bit lines, and a plurality of memory strings. Each memory string comprises a plurality of serially connected memory cells configured to store a plurality of encoded stored vectors. Each memory cell has a threshold voltage (VT) corresponding to the stored vector stored therein. The flash memory array is configured with a hybrid matching mechanism, the hybrid matching mechanism including an exact-search (ES) mode and an approximate-search (AS) mode. The bit line driver circuit is coupled to the plurality of bit lines of the flash memory array and is configured to apply voltage to each of the plurality of memory strings. The word line driver circuit is coupled to the plurality of word lines of the flash memory array and is coupled to a controller. The word line driver circuit is configured to generate a plurality of corresponding search voltages (VS) based on a query vector received from the controller, and apply the plurality of search voltages to gates of the plurality of memory cells. Wherein, in a first portion of each of the plurality of memory strings, the ES mode is executed to filter the memory strings, such that when a search voltage matches a threshold voltage, memory cells in the first portion conduct, and otherwise, the memory cells in the first portion do not conduct, thereby filtering corresponding memory strings and reducing power consumption. And, in a second portion of each of the plurality of memory strings, the AS mode is executed for memory strings wherein the memory cells in the first portion conducted, performing vector similarity measurement, such that when a search voltage is higher than a threshold voltage, all memory cells in the second portion conduct, generating a conduction current having a magnitude corresponding to a similarity between the search voltage and the threshold voltage. The sense amplifier circuit is coupled to each of the plurality of memory strings and is configured to measure the conduction current of each of the plurality of memory strings, select one or more of the plurality of memory strings based on magnitudes of the measured conduction currents in descending order, and determine the selected one or more memory strings as matching the query vector.

In order to achieve the objective, the present invention discloses an energy-efficient VSS method based on hybrid matching and executed in an IMS architecture. The method comprises the steps of: encoding a plurality of stored vectors into corresponding threshold voltages for storage in a flash memory array, the flash memory array comprising a plurality of memory strings, each memory string comprising a plurality of serially connected memory cells; receiving a query vector and generating corresponding search voltages based on the query vector, for application to gates of the memory cells in the flash memory array to trigger an electrical response; executing a hybrid matching mechanism, the hybrid matching mechanism including an exact-search mode and an approximate-search mode, wherein, in a first portion of each memory string, the exact-search mode is executed to filter the memory strings, such that when a search voltage matches a threshold voltage, memory cells in the first portion conduct, and otherwise, the memory cells in the first portion do not conduct, thereby filtering corresponding memory strings and reducing power consumption, and in a second portion of each memory string, the approximate-search mode is executed for memory strings wherein the memory cells in the first portion conducted, performing vector similarity measurement, such that when a search voltage is higher than a threshold voltage, all memory cells in the second portion conduct, generating a conduction current having a magnitude corresponding to a similarity between the search voltage and the threshold voltage; and measuring the conduction current of each memory string, selecting one or more of the plurality of memory strings based on magnitudes of the measured conduction currents in descending order, and determining the selected one or more memory strings as matching the query vector.

The system and method disclosed by the present invention differ from the prior art in that the present invention combines the exact-search mode and the approximate-search mode within the memory strings of the flash memory array. Exact search is performed in the first portion of the memory string to filter irrelevant memory strings and reduce power consumption. Approximate search is performed in the second portion of the filtered memory strings to measure vector similarity. Memory strings matching the query vector are selected based on the conduction current magnitude, thereby significantly reducing redundant searches.

Therefore, the above-mentioned solution of the present invention is able to achieve the technical effect of improving the energy efficiency of vector similarity search.

### BRIEF DESCRIPTION OF THE DRAWINGS

The structure, operating principle and effects of the present invention will be described in detail by way of various embodiments which are illustrated in the accompanying drawings.

FIG. 1 is a system block diagram of an energy-efficient vector similarity search system based on hybrid matching according to the present invention.

FIG. 2A to FIG. 2D are flowcharts of an energy-efficient vector similarity search method based on hybrid matching according to the present invention.

FIG. 3 is a schematic diagram of a flash memory array applying the present invention.

FIG. 4 is a schematic diagram of range encoding according to the present invention.

FIG. 5 is a schematic diagram illustrating shifting search voltages in the approximate-search mode applying the present invention.

FIG. 6 is a schematic diagram of filtering-aware training according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims.

These embodiments are provided so that this disclosure is thorough and complete, and fully conveys the inventive concept to those skilled in the art. Regarding the drawings, the relative proportions, and ratios of elements in the drawings may be exaggerated or diminished in size for the sake of clarity and convenience. Such arbitrary proportions are only illustrative and not limiting in any way. The same reference numbers are used in the drawings and description to refer to the same or like parts. As used herein, the singular forms “a”, “an” and “the” are intended to include the plural forms as well, unless the context clearly indicates otherwise.

It is to be acknowledged that, although the terms “first”, “second”, “third”, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on”, “connected to” or “coupled to” another element or layer, it can be directly on, connected or coupled to the other element or layer, or intervening elements or layers may be present. In contrast, when an element is referred to as being “directly on”, “directly connected to” or “directly coupled to” another element or layer, there are no intervening elements or layers present.

In addition, unless explicitly described to the contrary, the words “comprise” and “include”, and variations such as “comprises”, “comprising”, “includes”, or “including”, will be acknowledged to imply the inclusion of stated elements but not the exclusion of any other elements.

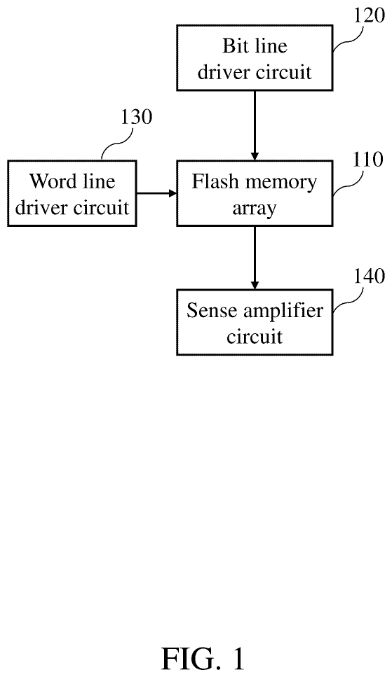

Please refer first to FIG. 1. FIG. 1 is a system block diagram of an energy-efficient vector similarity search system based on hybrid matching according to the present invention, configured for execution within an in-memory search architecture. The system comprises: a flash memory array 110 (e.g., NAND Flash), a bit line driver circuit 120, a word line driver circuit 130, and a sense amplifier circuit 140. The flash memory array 110 comprises a plurality of word lines, a plurality of bit lines, and a plurality of memory strings. Each memory string comprises a plurality of serially connected memory cells configured to store a plurality of encoded stored vectors. Each memory cell has a threshold voltage (VT) corresponding to the stored vector stored therein. The flash memory array is configured with a hybrid matching mechanism, the hybrid matching mechanism including an exact-search (ES) mode and an approximate-search (AS) mode. In practical implementation, when the memory cells are Multi-level Cells (MLC), each memory cell comprises a first sub-memory cell (Cell 1) and a second sub-memory cell (Cell 2). The threshold voltages and search voltages corresponding to the original five state encodings (i.e., “00”, “01”, “10”, “11”, and “xx”) can be extended to eight state encodings (i.e., “00”, “0x”, “01”, “x1”, “10”, “1x”, “11”, and “xx”). That is, the eight state encodings add states “0x”, “x1”, and “1x” to the five state encodings, where “x” represents a “don't care” state, which can be either “0” or “1”. For example, when the state is “0x”, it indicates that the first sub-memory cell is “0”, and the second sub-memory cell can be “0” or “1”. In this case, the threshold voltage of the first sub-memory cell is VT1 (threshold voltage level 1), the threshold voltage of the second sub-memory cell is VT3 (threshold voltage level 3), and the corresponding search voltages are VS2 (search voltage level 2) and VS4 (search voltage level 4), respectively. The levels of the first and second sub-memory cells for each state encoding and their corresponding threshold voltages and search voltages will be explained in detail later with reference to figures. Additionally, to reduce interference in the current distribution of the approximate-search mode, the “xx” state can be further excluded from the eight state encodings. It is particularly noted that due to the complementary configuration constraints of threshold voltages and search voltages, the state encoding “x0” does not exist. This is to ensure that sufficiently complementary voltages are set on the memory cell so that its state can be accurately identified.

The bit line driver circuit 120 is coupled to the plurality of bit lines of the flash memory array 110 and is configured to apply voltage to each of the plurality of memory strings. In practical implementation, the bit line driver circuit 120 can simultaneously manage 128k bit lines, with each bit line connected to one memory string. Cooperating with the sense amplifier circuit 140, it provides appropriate bit line voltages during a search operation to establish current paths, enabling all memory strings to perform vector similarity search in parallel. The sense amplifier circuit 140 measures the conduction current magnitude of each memory string, thereby realizing efficient large-scale parallel search operations.

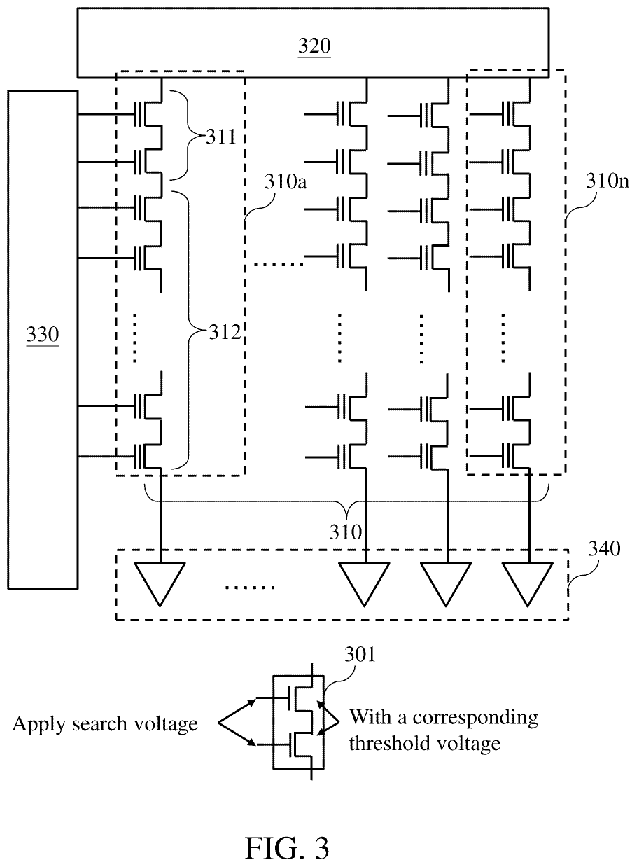

The word line driver circuit 130 is coupled to the plurality of word lines of the flash memory array 110 and coupled to a controller. The word line driver circuit is configured to generate a plurality of corresponding search voltages (VS) based on a query vector received from the controller, and apply the plurality of search voltages to gates of the plurality of memory cells. Wherein, in a first portion 111 (referring to FIG. 3) of each of the plurality of memory strings, the ES mode is executed to filter the memory strings, such that when a search voltage matches a threshold voltage, memory cells in the first portion conduct, and otherwise, the memory cells in the first portion do not conduct, thereby filtering corresponding memory strings and reducing power consumption. And, in a second portion 112 (referring to FIG. 3) of each of the plurality of memory strings, the AS mode is executed for memory strings wherein the memory cells in the first portion conducted, performing vector similarity measurement, such that when a search voltage is higher than a threshold voltage, all memory cells in the second portion conduct, generating a conduction current having a magnitude corresponding to a similarity between the search voltage and the threshold voltage. In practical implementation, the word line driver circuit 130 can further comprise circuitry configured to shift the search voltages applied to the memory cells in the second portion downwards by one overdrive (OD) level, to compensate for current distortion generated in the first portion and reduce the conduction current. For example, to mitigate the impact of the hybrid matching mechanism on the reliability of the approximate matching mode, the search voltage can be lowered, thereby reducing the total current in each memory string and thus reducing search energy consumption. Additionally, the controller can comprise a pre-trained neural network model, such as a Convolutional Neural Network (CNN) or similar. The neural network model performs Filtering-aware Training (FAT) during the training phase. The FAT initializes weights based on inter-class variance and intra-class variance of support vectors. In the backpropagation path, it uses a Sigmoid Function via differentiation to simulate the discontinuous filtering behavior of the first portion to generate gradients, and updates the weights of the neural network model based on the generated gradients to complete the training. This ensures that the trained neural network model deployed in the controller generates query vectors suitable for the hybrid matching mechanism.

The sense amplifier circuit 140 is coupled to each of the plurality of memory strings and is configured to measure the conduction current of each of the plurality of memory strings, select one or more of the plurality of memory strings based on magnitudes of the measured conduction currents in descending order, and determine the selected one or more memory strings as matching the query vector. In practical implementation, assuming the flash memory array 110 comprises 128k memory strings, then each memory string is connected to a sense amplifier, so the sense amplifier circuit 140 will comprise 128k sense amplifiers to achieve large-scale parallel measurement. During a search operation, all sense amplifiers simultaneously measure the conduction current magnitude of their respective corresponding memory strings. This conduction current magnitude reflects the similarity between the stored vector and the query vector: a larger conduction current indicates higher similarity. Based on the measured current values, the sense amplifier circuit 140 sorts them in descending order and selects the top N (where N is a positive integer) memory strings with the largest conduction currents (e.g., selecting the most similar class in few-shot learning, or selecting the top 100 nearest neighbors in approximate nearest-neighbor search). These selected memory strings are then determined as the search results that best match the query vector, thus completing the vector similarity search task.

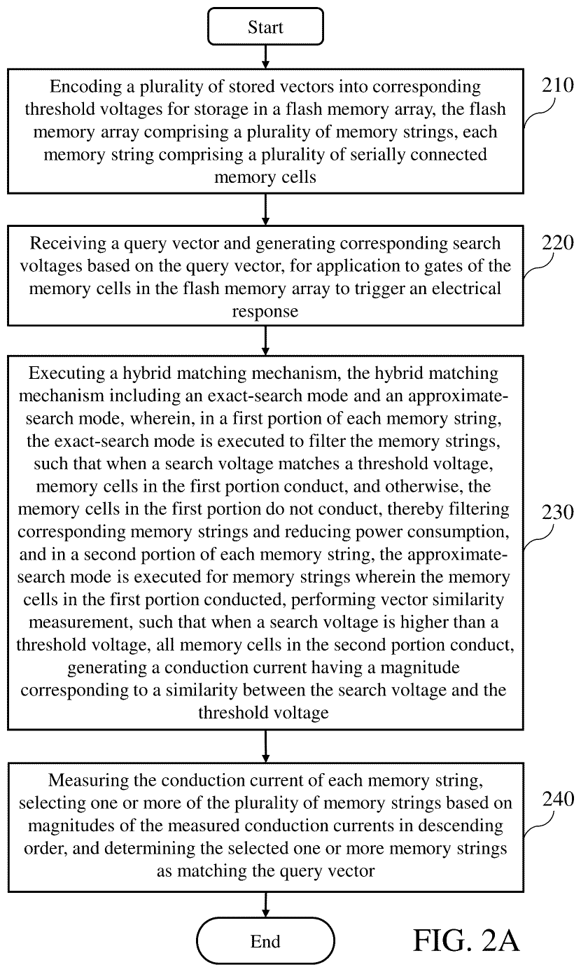

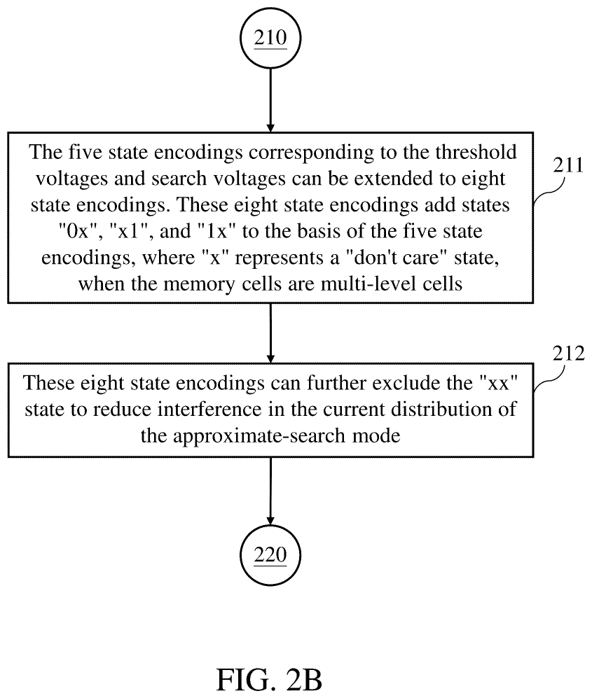

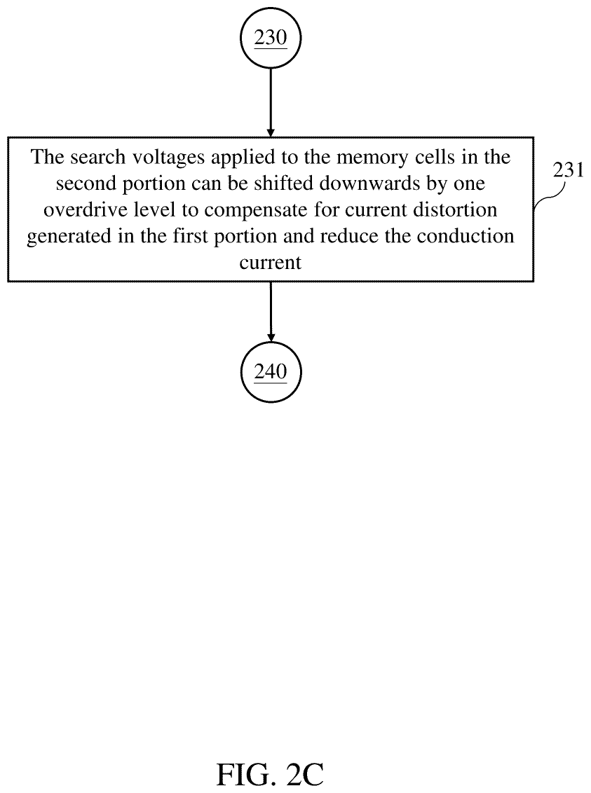

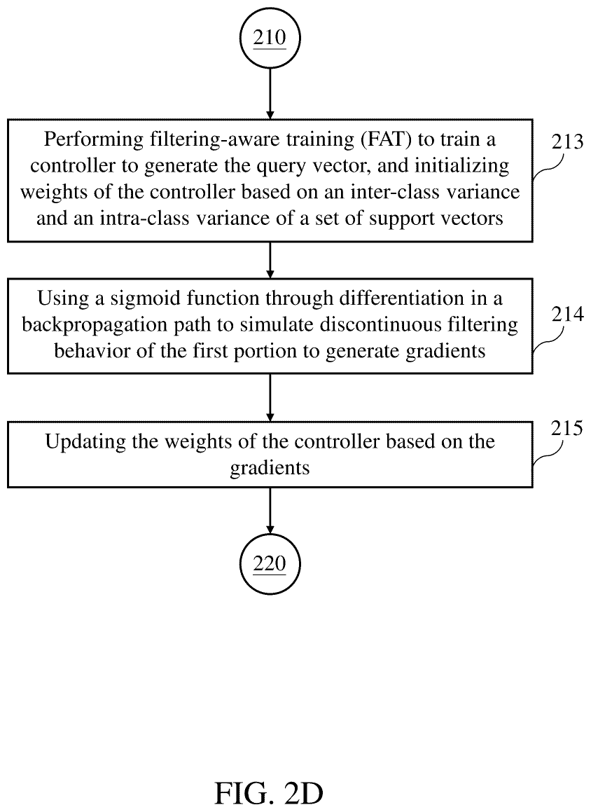

Please refer to FIG. 2A to FIG. 2D. FIG. 2A to FIG. 2D are flowcharts of an energy-efficient vector similarity search method based on hybrid matching according to the present invention, executed in an in-memory search architecture. The steps comprise: encoding a plurality of stored vectors into corresponding threshold voltages for storage in a flash memory array 110, the flash memory array 110 comprising a plurality of memory strings, each memory string comprising a plurality of serially connected memory cells (Step 210); receiving a query vector and generating corresponding search voltages based on the query vector, for application to gates of the memory cells in the flash memory array 110 to trigger an electrical response (Step 220); executing a hybrid matching mechanism, the hybrid matching mechanism including an exact-search mode and an approximate-search mode, wherein, in a first portion of each memory string, the exact-search mode is executed to filter the memory strings, such that when a search voltage matches a threshold voltage, memory cells in the first portion conduct, and otherwise, the memory cells in the first portion do not conduct, thereby filtering corresponding memory strings and reducing power consumption, and in a second portion of each memory string, the approximate-search mode is executed for memory strings wherein the memory cells in the first portion conducted, performing vector similarity measurement, such that when a search voltage is higher than a threshold voltage, all memory cells in the second portion conduct, generating a conduction current having a magnitude corresponding to a similarity between the search voltage and the threshold voltage (Step 230); and measuring the conduction current of each memory string, selecting one or more of the plurality of memory strings based on magnitudes of the measured conduction currents in descending order, and determining the selected one or more memory strings as matching the query vector (Step 240). Through the above steps, by combining the exact-search mode and the approximate-search mode within the memory strings of the flash memory array 110, exact search is performed in the first portion of the memory string to filter irrelevant memory strings and reduce power consumption, approximate search is performed in the second portion of the filtered memory strings to measure vector similarity, and memory strings matching the query vector are selected based on the conduction current magnitude, thereby significantly reducing redundant searches.

Specifically, when the memory cells are multi-level cells, as shown in FIG. 2B, the five state encodings corresponding to the threshold voltages and search voltages can be extended to eight state encodings. These eight state encodings add states “0x”, “x1”, and “1x” to the basis of the five state encodings, where “x” represents a “don't care” state (Step 211); and these eight state encodings can further exclude the “xx” state to reduce interference in the current distribution of the approximate-search mode (Step 212). Additionally, as shown in FIG. 2C, after Step 230, the search voltages applied to the memory cells in the second portion can be shifted downwards by one overdrive level to compensate for current distortion generated in the first portion and reduce the conduction current (Step 231). Furthermore, after Step 210, as shown in FIG. 2D, a filtering-aware training can be performed to train a controller to generate the query vector. The filtering-aware training initializes weights of the controller based on inter-class variance and intra-class variance of support vectors (Step 213); in the backpropagation path, uses a Sigmoid Function via differentiation to simulate the discontinuous filtering behavior of the first portion to generate gradients (Step 214); and updates the weights of the controller based on the gradients (Step 215).

An embodiment of the present invention will be illustrated in the following paragraphs with reference to FIG. 3 to FIG. 6. Please refer to FIG. 3. FIG. 3 is a schematic diagram of a flash memory array applying the present invention. In actual implementation, the flash memory array 310 comprises a plurality of memory strings (310a˜310n). Each memory string (310a˜310n) further comprises a plurality of serially connected memory cells 301. Wherein, two memory cells 301 connected in series form a word, so each memory string (310a˜310n) comprises multiple words for storing encoded stored vectors. Additionally, a bit line driver circuit 320 is coupled to the bit lines of the flash memory array 310; a word line driver circuit 330 is coupled to the word lines of the flash memory array 310 to apply search voltages to the gates of the memory cells 301; a sense amplifier circuit 340 is coupled to each memory string (310a˜310n) to measure its conduction current. The search voltages applied to the gates of the memory cells 301 enable parallel search across memory cells 301 in the same word line. Specifically, within each memory string (310a˜310n), to simultaneously use the exact-search mode and the approximate-search mode, each memory string (310a˜310n) is divided into two portions. Taking memory string 310a as an example, the word lines of the first portion 311 are used for the exact-search mode to filter irrelevant stored vectors by selectively disabling memory strings, resulting in zero current for the memory string, thereby reducing energy consumption. The word lines of the second portion 312 are used for the approximate-search mode to perform vector similarity search. In the approximate-search mode, the memory string generates a conduction current inversely proportional to the mismatch level. This ensures that only relevant memory strings participate in the vector similarity search, achieving low-power operation.

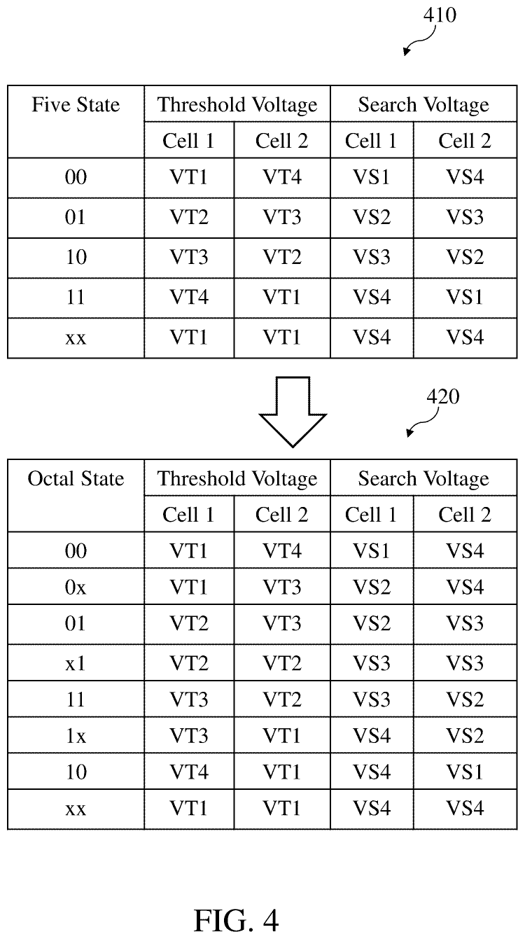

As illustrated in FIG. 4, FIG. 4 is a schematic diagram of range encoding according to the present invention. Due to the simultaneous use of the exact-search mode and the approximate-search mode in a fixed-length memory string (310a˜310n), the available quantity of memory cells 301 for the approximate-search mode is inevitably sacrificed. Therefore, extensive use of word lines in the exact-search mode is undesirable. Improving filtering effectiveness under the constraint of limited word lines becomes a critical issue. As shown by the pre-expansion range encoding 410, a conventional MLC has two bits and can represent five states: “00”, “01”, “10”, “11”, and “xx”. Two bits can be encoded through complementary threshold voltages, where VT1 to VT4 represent different levels (low to high) of threshold voltage, each having a different voltage range; VS1 to VS4 represent different levels (low to high) of search voltage, also having different voltage ranges. However, to improve filtering efficiency, the present invention adds three states, “0x”, “x1”, and “1x”, on top of this basis, expanding it from five states to eight states (as shown by the post-expansion range encoding 420), and sets corresponding levels of threshold voltage. After state expansion, it can determine whether a value falls within a range, rather than just comparing a specific value. That is, the purpose of the exact-search mode is not to find identical data, but to quickly filter out obviously different data. Thus, by expanding to eight state encodings, the required codeword length can be reduced while maintaining the effective matching interval for filtering. In practical implementation, a constrained programming (CP) algorithm can be used to find the most accurate and efficient encoding method for the exact-search mode, achieving more flexible and precise matching. This transforms the original “point-in-range” comparison into a “range-to-range” matching scheme. On the other hand, to determine if the query vector and the stored vector are similar, a predefined threshold “H” can be used as a filtering criterion. When the numerical difference between the query vector and the stored vector in a specific dimension is within the threshold range, the stored vector is considered a potentially similar vector and then enters the approximate-search mode. Conversely, if the difference is greater than the threshold, the stored vector is directly filtered out. In this case, the memory cells in the first portion will not conduct, so the entire corresponding memory string will not generate current, thus achieving power saving. Additionally, due to the limited storage space of each memory string (310a˜310n), only one MLC word is allocated for the exact-search mode in each memory string (310a˜310n). When the threshold “H” is large, it can be split, with half used for the stored vector (e.g., hs=H/2) and the other half for the query vector (e.g., hq=H/2).

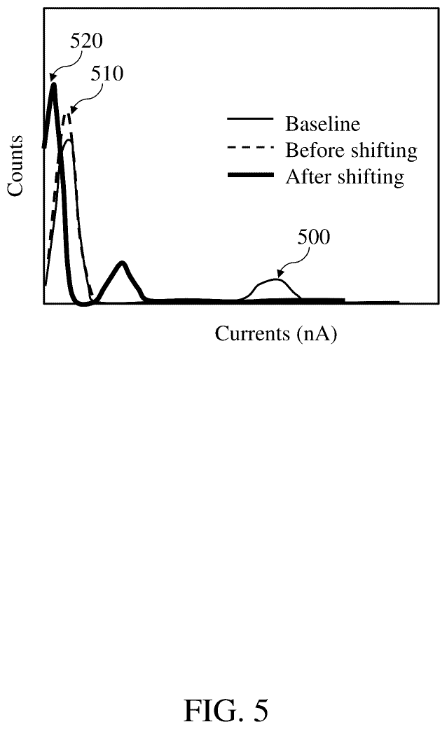

As illustrated in FIG. 5, FIG. 5 is a schematic diagram illustrating shifting search voltages in the approximate-search mode applying the present invention. In the hybrid matching mechanism, conducting memory strings are affected by mismatch levels from both the exact-search mode and the approximate-search mode. The mismatch level represents the degree of mismatch between the query vector and the stored vector. This mismatch level determination is based on the overdrive (OD) voltage level, i.e., the voltage difference between the applied search voltage and the threshold voltage within the memory cell (OD=VS−VT). Wherein, the “mismatch level” is inversely proportional to the “overdrive voltage level”; a smaller OD value represents a higher mismatch level. For example, 0 to 3 OD are mapped to mismatch levels 3 to 0, respectively. The largest mismatch level significantly reduces the matching current. Although memory cells in the approximate-search mode generate current proportional to similarity, the mismatch levels from memory cells in the exact-search mode can disrupt this correlation (e.g., mismatch levels 2, 3), degrading the accuracy of vector similarity search. The effect of mismatch level 3 is particularly severe, causing disproportionate current drops. Furthermore, the “xx” codeword in the exact-search mode spans multiple threshold voltage intervals, causing mismatch levels to vary between 0 and 3 without any meaningful correlation to vector similarity. This increases current inconsistency and further degrades matching accuracy. Therefore, to address this situation, the “xx” state can be removed from the eight states, and the remaining codewords generated by the constrained programming algorithm can be used. Then, in the approximate-search mode, the search voltage is shifted by one OD, for example, by shifting all applied search voltages downwards (decreasing) by one overdrive voltage level. This can mitigate the impact of high mismatch levels from memory cells in the exact-search mode. As shown in FIG. 5, the solid line represents the baseline 500. Before shifting (dashed line 510), the current is suppressed, leading to poor current separation. After shifting (solid line 520), the suppressed current is successfully restored, and the separation is improved, allowing the sense amplifier to clearly distinguish different current levels. If the search voltage is not shifted, the current peak of the approximate-search mode will be suppressed, making it impossible for the sense amplifier to clearly distinguish different current magnitudes, thereby increasing sense amplifier errors. Conversely, shifting the search voltage restores the current peak, improves current separation, and enhances the accuracy of vector similarity search.

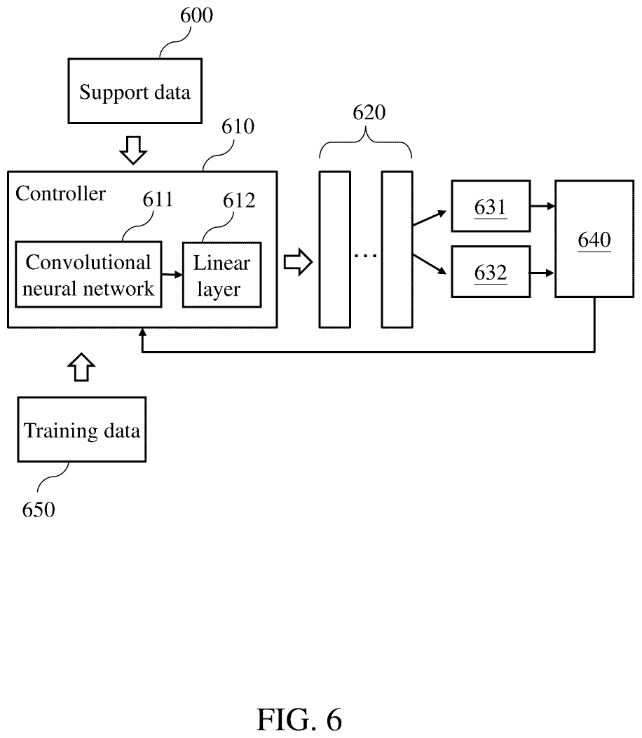

As illustrated in FIG. 6, FIG. 6 is a schematic diagram of filtering-aware training according to the present invention. Implementing the hybrid matching mechanism may encounter issues of decreased accuracy and ineffective filtering. Therefore, “inter-class variance” and “intra-class variance” can be taken into consideration. Specifically, FAT can be developed based on the Hardware-aware Training (HAT) framework. This framework incorporates flash memory characteristics into training, such as modeling current variations, quantization errors, and Multi-bit Thermometer Code (MTMC) behavior. Based on the behavioral differences between the exact-search mode and the approximate-search mode, the controller can adapt to the hybrid matching mechanism and improve reliability and energy efficiency. For example, during training, support data 600 (e.g., images of known classes) can be input into a pre-trained convolutional neural network 611 and a linear layer 612 to extract support vectors 620 representing each class. Then, all dimensions of the support vectors 620 are analyzed, and two key metrics are calculated for each dimension: inter-class variance and intra-class variance. Next, based on intra-class variance sorting, a portion with the lowest variance (most stable) is selected, averaged, and used as the initial weights for the filter, intended for the exact-search mode 631. Simultaneously, based on inter-class variance sorting, a portion with the highest variance (most discriminative) is selected as the initial weights for the classifier, intended for the approximate-search mode 632. Then, these two types of weights are combined to form the initial weights for the hybrid matching mechanism. Subsequently, training data 650 is input into the convolutional neural network 611 and the linear layer 612. The output vector is transmitted to a module 640 simulating a Multi-bit Content-Addressable Memory (MCAM). A Sigmoid function is used to simulate the filtering behavior of the exact-search mode, and the MTMC encoding and sense amplifier behavior of the approximate-search mode are simulated. The simulated matching results are aggregated into a final prediction result through a voting mechanism. The prediction result is then compared with the correct label to calculate the loss. Next, the gradient generated by the loss is propagated back to the controller 610 through a backward optimization algorithm to update the weights until convergence. Finally, the trained controller 610 can generate vectors fully adapted to the hybrid matching mechanism, achieving optimal energy saving and accuracy performance.

In summary, it is evident that the difference between the present invention and the prior art lies in combining the exact-search mode and the approximate-search mode within the memory strings of the flash memory array. Exact search is performed in the first portion of the memory string to filter irrelevant memory strings and reduce power consumption. Approximate search is performed in the second portion of the filtered memory strings to measure vector similarity. Memory strings matching the query vector are selected based on the conduction current magnitude, thereby significantly reducing redundant searches. Through this technical means, the problems existing in the prior art can be solved, thereby achieving the technical effect of improving the energy efficiency of vector similarity search.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. An energy-efficient vector similarity search (VSS) system based on hybrid matching and configured for execution within an in-memory search (IMS) architecture, the system comprising:
a flash memory array comprising a plurality of word lines, a plurality of bit lines, and a plurality of memory strings, each of the plurality of memory strings comprising a plurality of serially connected memory cells configured to store a plurality of encoded stored vectors, each of the plurality of memory cells having a threshold voltage (VT) corresponding to a encoded stored vector, wherein the flash memory array is configured with a hybrid matching mechanism, the hybrid matching mechanism including an exact-search (ES) mode and an approximate-search (AS) mode;
a bit line driver circuit coupled to the plurality of bit lines of the flash memory array, the bit line driver circuit configured to apply voltages to each of the plurality of memory strings;
a word line driver circuit coupled to the plurality of word lines of the flash memory array and coupled to a controller, the word line driver circuit configured to:
generate a plurality of corresponding search voltages (VS) based on a query vector from the controller;
apply the search voltages to gates of the plurality of memory cells;
in a first portion of each of the plurality of memory strings, the ES mode is executed to filter the memory strings, such that when a search voltage matches a threshold voltage, memory cells in the first portion conduct, and otherwise, the memory cells in the first portion do not conduct, thereby filtering corresponding memory strings and reducing power consumption; and
in a second portion of each of the plurality of memory strings, the AS mode is executed for memory strings whose memory cells in the first portion conduct, to perform vector similarity measurement, such that when a search voltage is higher than a threshold voltage, all memory cells in the second portion conduct, generating a conduction current having a magnitude corresponding to a similarity between the search voltage and the threshold voltage; and
a sense amplifier circuit coupled to each of the plurality of memory strings, the sense amplifier circuit configured to:
measure the conduction current of each of the plurality of memory strings;
select one or more of the plurality of memory strings based on magnitudes of the measured conduction currents in descending order; and
determine the selected one or more memory strings as matching the query vector.

2. The energy-efficient VSS system based on hybrid matching of claim 1, wherein when the memory cells are multi-level cells (MLC), each of the plurality of memory cells comprises a first sub-memory cell and a second sub-memory cell, and five state encodings corresponding to the threshold voltage and the search voltage are expanded into eight state encodings, the eight state encodings adding “0x”, “x1”, and “1x” states to a basis of the five state encodings, wherein “x” represents a don't care state.

3. The energy-efficient VSS system based on hybrid matching of claim 2, wherein the eight state encodings further exclude a state “xx” to reduce interference in a current distribution of the AS mode.

4. The energy-efficient VSS system based on hybrid matching of claim 1, wherein the word line driver circuit further comprises circuitry configured to shift downward the search voltages applied to the memory cells of the second portion by one overdrive (OD) voltage level to compensate for current distortion generated in the first portion and reduce the conduction current.

5. The energy-efficient VSS system based on hybrid matching of claim 1, wherein the controller comprises a pre-trained neural network model, the neural network model configured to perform filtering-aware training (FAT) during a training phase, wherein the FAT:
initializes weights based on an inter-class variance and an intra-class variance of support vectors;
in a backpropagation path, uses a sigmoid function through differentiation to simulate discontinuous filtering behavior of the first portion to generate gradients; and
updates weights of the neural network model based on the gradients to complete training, such that the trained neural network model deployed in the controller generates query vectors suitable for the hybrid matching mechanism.

6. An energy-efficient vector similarity search (VSS) method based on hybrid matching and executed in an in-memory search (IMS) architecture, the method comprising:
encoding a plurality of encoded stored vectors into corresponding threshold voltages (VT) for storage in a flash memory array, wherein the flash memory array comprises a plurality of memory strings, and each memory string comprises a plurality of memory cells arranged in series;
receiving a query vector and generating corresponding search voltages (VS) based on the query vector for application to gates of the memory cells in the flash memory array to trigger electrical responses;
executing a hybrid matching mechanism, wherein the hybrid matching mechanism includes an exact-search (ES) mode and an approximate-search (AS) mode, wherein:
in a first portion of each of the plurality of memory strings, the ES mode is executed to filter the memory strings, such that when a search voltage matches a threshold voltage, memory cells in the first portion conduct, and otherwise, the memory cells in the first portion do not conduct, thereby filtering corresponding memory strings and reducing power consumption; and
in a second portion of each of the plurality of memory strings, the AS mode is executed for memory strings whose memory cells in the first portion conduct, performing vector similarity measurement, such that when a search voltage is higher than a threshold voltage, all memory cells in the second portion conduct, generating a conduction current having a magnitude corresponding to a similarity between the search voltage and the threshold voltage; and
measuring the conduction current of each of the plurality of memory strings, selecting one or more of the plurality of memory strings based on magnitudes of the measured conduction currents in descending order, and determining the selected one or more memory strings as matching the query vector.

7. The energy-efficient VSS method based on hybrid matching of claim 6, wherein when the memory cells are multi-level cells (MLC), each of the plurality of memory cells comprises a first sub-memory cell and a second sub-memory cell, and the method further comprises expanding five state encodings corresponding to the threshold voltage and the search voltage to eight state encodings, the eight state encodings adding “0x”, “x1”, and “1x” states to a basis of the five state encodings, wherein “x” represents a don't care state.

8. The energy-efficient VSS method based on hybrid matching of claim 7, wherein the eight state encodings further exclude a state “xx” to reduce interference in a current distribution of the AS mode.

9. The energy-efficient VSS method based on hybrid matching of claim 6, further comprising shifting the search voltages applied to the memory cells in the second portion downward by one overdrive (OD) voltage level to compensate for current distortion generated in the first portion and reduce the conduction current.

10. The energy-efficient VSS method based on hybrid matching of claim 6, further comprising performing filtering-aware training (FAT) to train a controller to generate the query vector, wherein the FAT comprises:
initializing weights of the controller based on an inter-class variance and an intra-class variance of a set of support vectors;
using a sigmoid function through differentiation in a backpropagation path to simulate discontinuous filtering behavior of the first portion to generate gradients; and
updating the weights of the controller based on the gradients.
